(19) United States
(12) Patent Application Publication
(10) Pub. No.: US 2025/0318326 A1
(43) Pub. Date: Oct. 9, 2025

(54) SEMICONDUCTOR DEVICE AND SEMICONDUCTOR MODULE HAVING THE SAME

(71) Applicant: EPISTAR CORPORATION, Hsinchu (TW)

(72) Inventors: Hsin-Ying WANG, Hsinchu (TW); Chao-Hsing CHEN, Hsinchu (TW); Yu-Ting HUANG, Hsinchu (TW)

(21) Appl. No.: 18/627,056

(22) Filed: Apr. 4, 2024

(51) Int. Cl. H01L 33/38; H01L 25/075; H01L 33/62

(52) U.S. Cl. CPC H10H 20/8312; H01L 25/0753; H10H 20/857

(57) ABSTRACT

A light-emitting device includes: a semiconductor stack, including a first semiconductor layer, an active region and a second semiconductor layer; an electrode structure, formed on and electrically connected with the semiconductor stack, including a pad electrode structure and a bonding electrode structure formed on the pad electrode structure; and a first insulating structure formed on the pad electrode structure; wherein the electrode structure comprises a first slit set, the first slit set comprises a first slit in the pad electrode structure and a second slit in the bonding electrode structure, wherein in a plan view, the second slit overlaps and corresponds to the first slit.

### BACKGROUND

### Technical Field

The present application relates to a semiconductor device having an electrode structure with a slit set, and a semiconductor module having the same.

### Description of the Related Art

A semiconductor device includes compound semiconductors composed of group III-V elements, such as gallium phosphide (GaP), gallium arsenide (GaAs), gallium nitride (GaN), and aluminum nitride (AlN). The semiconductor device may be a semiconductor optoelectronic device, such as a light-emitting diode (LED), lasers, a light detector, a solar cell, power devices, or acoustic wave devices. Light-emitting diodes of semiconductor optoelectronic device have the characteristics of low power consumption, low heat-generation, long lifetime, compact size, high response speed and stable emission wavelength. Thus, light-emitting diodes have been widely used in household appliances, indicator lights and optoelectronic products.

Conventional light-emitting diode includes a substrate, an n-type semiconductor layer, an active layer and a p-type semiconductor layer formed on the substrate, and a p-electrode and an n-electrode formed on the p-type and the n-type semiconductor layers, respectively. When light-emitting diode is conducted through the electrode and operates under a specific forward bias, holes from the p-type semiconductor layer and electrons from the n-type semiconductor layer combine in the active layer to emit light.

### SUMMARY

A light-emitting device includes: a semiconductor stack, including a first semiconductor layer, an active region and a second semiconductor layer; an electrode structure, formed on and electrically connected with the semiconductor stack, including a pad electrode structure and a bonding electrode structure formed on the pad electrode structure; and a first insulating structure formed on the pad electrode structure; wherein the electrode structure comprises a first slit set, the first slit set comprises a first slit in the pad electrode structure and a second slit in the bonding electrode structure, wherein in a plan view, the second slit overlaps and corresponds to the first slit.

### BRIEF DESCRIPTION OF THE DRAWINGS

FIG. 1A shows a plan view of a light-emitting device 1 in accordance with an embodiment of the present application.

FIG. 1B shows a cross-sectional view taken along A-A′ line in FIG. 1A.

FIG. 1C shows a cross-sectional view taken along B-B′ line in FIG. 1A.

FIG. 1D shows a simplified plan view of the light-emitting device 1 shown in FIG. 1A.

FIG. 2A shows a plan view of a light-emitting device 2 in accordance with another embodiment of the present application.

FIG. 2B shows a cross-sectional view taken along A-A′ line in FIG. 2A.

FIG. 2C shows a cross-sectional view taken along B-B′ line in FIG. 2A.

FIG. 2D shows a cross-sectional view taken along C-C′ line in FIG. 2A.

FIG. 3A shows a plan view of a light-emitting device 3 in accordance with another embodiment of the present application.

FIG. 3B shows a cross-sectional view taken along A-A′ line in FIG. 3A.

FIG. 3C shows a cross-sectional view taken along B-B′ line in FIG. 3A.

FIG. 4A shows a plan view of a light-emitting device 4 in accordance with another embodiment of the present application.

FIG. 4B shows a cross-sectional view taken along A-A′ line in FIG. 4A.

FIG. 4C shows a simplified plan view of the light-emitting device 4.

FIGS. 5A-5D show schematic top views of the pad electrode structure and the bonding electrode structure in accordance with modified embodiments of the present application.

FIG. 6 shows a schematic cross-sectional view of a light-emitting module in accordance with an embodiment of the present application.

### DETAILED DESCRIPTION

In order to make the description of the present application more detailed and complete, please refer to the description of the following embodiments and cooperate with the relevant illustrations. However, the examples shown below are used to illustrate the light-emitting device of the present application, and the present application is not limited to the following embodiments. In addition, the dimensions, materials, shapes, relative arrangements, etc. of the elements described in the embodiments in this specification are not limited to the description, and the scope of the present application is not limited to these, but is merely a description. In addition, the size or positional relationship of the elements shown in each figure is exaggerated for clear description. Furthermore, in the following description, in order to appropriately omit detailed descriptions, elements of the same or similar nature are shown with the same names and symbols.

A semiconductor device and a semiconductor module are provided in some embodiments of the present application. The semiconductor device in some embodiments may be semiconductor optoelectronic device, such as a light-emitting diode (LEDs), laser, light detector, solar cell, or power device. The primary structure of a semiconductor device includes a buffer layer and a device structure formed on the buffer layer. Different device structures may be formed depending on the device functions. For example, the device structure of a light-emitting device may be a semiconductor stack including a p-type semiconductor layer, an n-type semiconductor layer and an active region. The active region may emit light in different wavelength bands in accordance with the material composition. A plurality of embodiments is provided below as relevant descriptions of the semiconductor device and the semiconductor module, and it is understood that each semiconductor device in these embodiments is for illustrative purposes only instead of intending to limit the present disclosure.

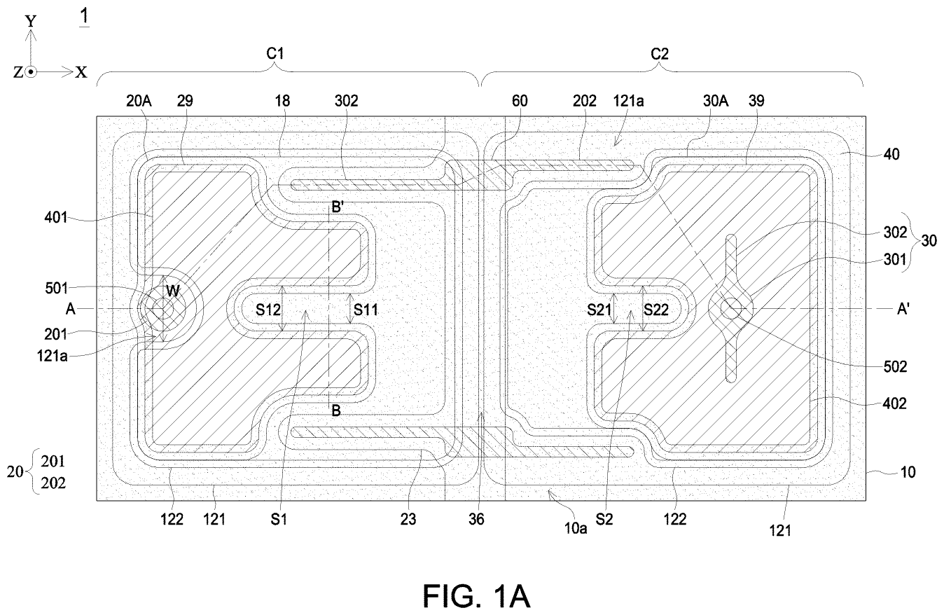

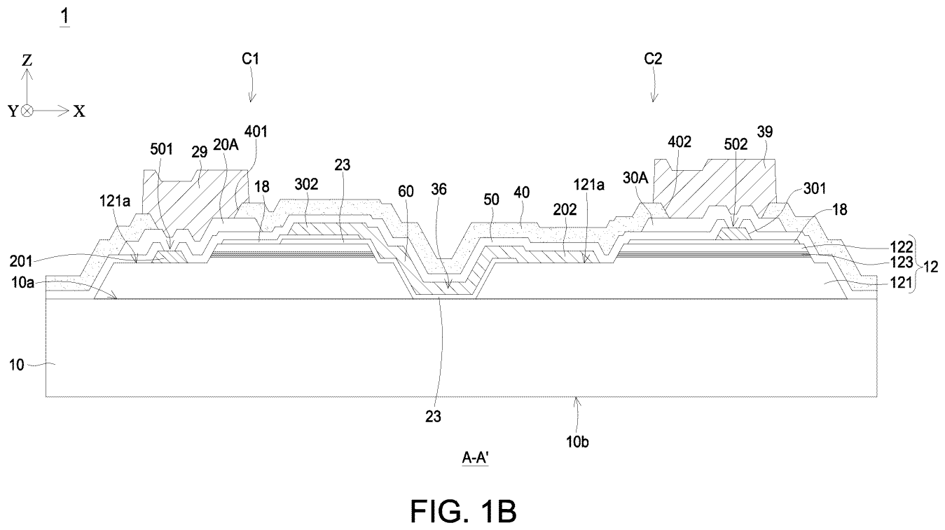

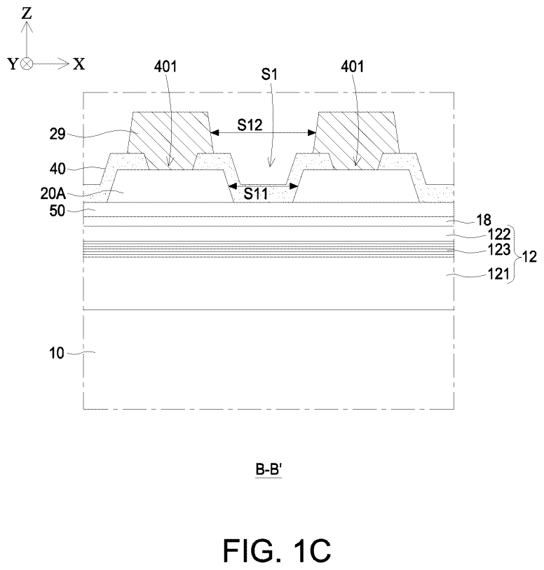

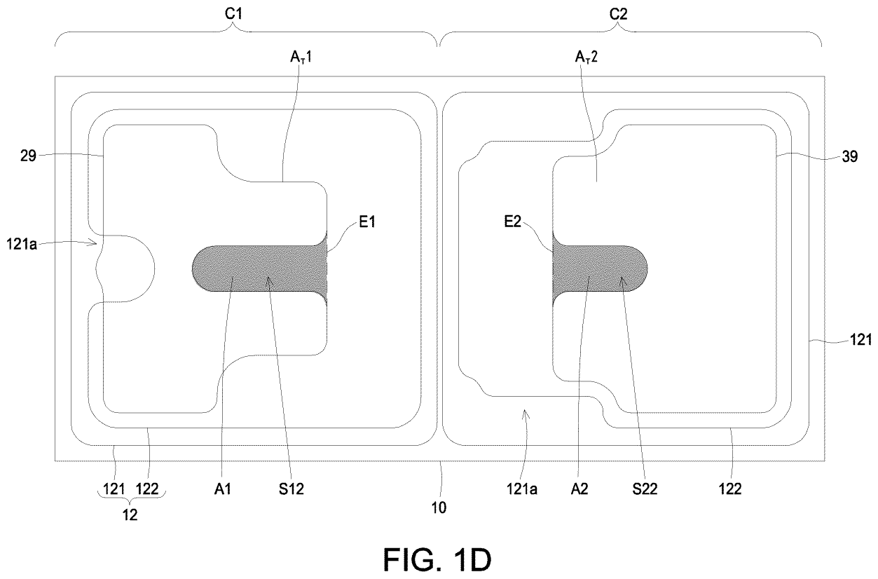

Referring to FIGS. 1A, 1B and 1C, in accordance with some embodiments, an embodiment of taking a light-emitting device 1 as the semiconductor device is illustrated. FIG. 1A shows a plan view of the light-emitting device 1 in accordance with the embodiment of the present application. FIG. 1B shows a cross-sectional view taken along an A-A′ line in FIG. 1A. FIG. 1C shows a cross-sectional view taken along a B-B′ line in FIG. 1A.

As shown in FIG. 1A and FIG. 1B, the light-emitting device 1 includes a substrate 10 and a semiconductor stack 12 formed on a top surface 10a of the substrate 10, wherein the semiconductor stack 12 includes a plurality of units, for example, a first unit C1 and a second unit C2 separated from each other by a trench 36. Each of the units C1 and C2 of the semiconductor stack 12 includes a first semiconductor layer 121 formed on the substrate 10, and a semiconductor mesa including an active region 123 and a second semiconductor layer 122 formed on the first semiconductor layer 121. The semiconductor stack 12 includes recesses exposing an upper surface 121a of the first semiconductor layer 121. The upper surface 121a is not covered by the semiconductor mesa. In one embodiment, in the plan view, the recesses are disposed at a periphery region and/or in a central region of the semiconductor stack 12. The recess which is disposed along the periphery region surrounds the semiconductor mesa. The recesses disposed at the periphery region and in the central region can be connected or isolated. Nevertheless, the present embodiment is not limited thereto.

The substrate 10 can be a growth substrate. The substrate 10 includes GaAs or GaP for growing AlGaInP based semiconductor thereon. The substrate 10 includes Al₂O₃, GaN, SiC, Si, or AlN for growing InGaN based or AlGaN based semiconductor thereon. In one embodiment, the substrate 10 can be a patterned substrate; that is, the substrate 10 includes patterned structures (not shown) on the top surface 10a. In one embodiment, the light generated from the semiconductor stack 12 is refracted, reflected or scattered by the patterned structures, thereby increasing the brightness of the light-emitting device. In addition, the patterned structures lessen or suppress the dislocation caused by lattice mismatch between the substrate 10 and the semiconductor stack 12, thereby improving the epitaxy quality of the semiconductor stack 12.

In an embodiment of the present application, the semiconductor stack 12 is formed on the substrate 10 by metal-organic chemical vapor deposition (MOCVD), molecular beam epitaxy (MBE), hydride vapor epitaxy (HVPE) or ion plating such as sputtering or evaporating.

In one embodiment, the semiconductor stack 12 further includes a buffer structure (not shown) between the first semiconductor layer 121 and the substrate 10. The buffer structure 120 reduces the lattice mismatch and suppresses dislocation so as to improve the epitaxy quality. The material of the buffer structure includes GaN, AlGaN, or AlN. In an embodiment, the buffer structure includes a plurality of sub-layers (not shown) and the sub-layers include the same materials or different materials. In one embodiment, the buffer structure includes two sub-layers formed by different methods. For example, a first sub-layer of the buffer structure is grown by sputtering and a second sub-layer of the buffer structure is grown by MOCVD. In another embodiment, the buffer structure further includes a third sub-layer. The third sub-layer is grown by MOCVD, and the growth temperature of the second sub-layer is different from the growth temperature of the third sub-layer. In an embodiment, the first, second, and third sub-layers include the same material, such as AlN. In one embodiment, the first semiconductor layer 121 and the second semiconductor layer 122 are, for example, cladding layers or confinement layers. The first semiconductor layer 121 and the second semiconductor layer 122 have different conductivity types, different electrical properties, different polarities or different dopants for providing electrons or holes. For example, the first semiconductor layer 121 is composed of n-type semiconductor and the second semiconductor layer 122 is composed of p-type semiconductor. The active region 123 is formed between the first semiconductor layer 121 and the second semiconductor layer 122. When being driven by a current, electrons and holes are combined in the active region 123 to convert electrical energy into optical energy for illumination. The wavelength of the light generated by the light-emitting device 1 or by the semiconductor stack 12 can be adjusted by changing the physical properties and chemical composition of one or more layers in the semiconductor stack 12.

The material of the semiconductor stack 12 includes III-V compound semiconductor such as AlₓIn_{y}Ga_{(1-x-y)}N (i.e. AlInGaN base) or AlₓIn_{y}Ga_{(1-x-y)}P (i.e. AlInGaP base), where 0≤x, y≤1; x+y≤1. When the material of the semiconductor stack 12 includes AlInGaP based material, the semiconductor stack 12 emits red light having a wavelength between 610 nm and 650 nm or yellow light having a wavelength between 550 nm and 570 nm. When the material of the semiconductor stack 12 includes AlInGaN based material, the semiconductor stack 12 emits blue light or deep blue light having a wavelength between 400 nm and 490 nm, green light having a wavelength between 490 nm and 550 nm or UV light having a wavelength between 250 nm and 400 nm. The active region 123 can be a single hetero-structure (SH), a double hetero-structure (DH), a double-side double hetero-structure (DDH), or a multi-quantum well (MQW) structure. The material of the active region 123 can be i-type, p-type or n-type semiconductor.

A first contact structure 20 is formed on the upper surface 121a of the first semiconductor layer 121 in the recess and electrically connected to the first semiconductor layer 121. In one embodiment shown in FIG. 1A, the first contact structure 20 includes a first contact part 201 formed on the first semiconductor layer 121 of the first unit C1 and first finger parts 202 formed on the first semiconductor layer 121 of the second unit C2. In another embodiment, the first contact structure 20 includes the first contact part 201 and the first finger part 202 extending from the first contact part 201. A transparent conductive layer 18 and a second contact structure 30 are formed on and electrically connected to the second semiconductor layer 122. In one embodiment shown in FIG. 1A, the second contact structure 30 includes a second contact part 301 and second finger parts 302 extending from the second contact part 301 formed the second unit C2 and another second finger parts 302 formed on the first unit C1. Connecting structures 60 are separately disposed between the first and the second units C1 and C2. The two ends of one connecting structure 60 are respectively connected to the second finger part 302 on the first unit C1 and the first finger part 202 on the second unit C2, so that the units C1 and C2 are electrically connected in serial and form a light-emitting array. In the present application, the number of the units of the semiconductor stack 12 and the number of the connecting structure 60 are not limited thereto. The light-emitting device 1 can includes more than two units, and more than two connecting structures 60 or single connecting structure 60 can be formed between two adjacent units. In another embodiment, the plurality units of the semiconductor stack 12 can be electrically connected in parallel.

The transparent conductive layer 18 can spread current and provide good electrical contact with the second semiconductor layer 122, such as ohmic contact. The transparent conductive layer 18 is transparent to the light emitted from the active region 123. For example, the transparent conductive layer 18 has a transmittance of more than 80% to the light emitted from the active region 123. The material of the transparent conductive layer 18 can be a metal or a transparent conductive material. The metal material includes Au, NiAu, etc. The transparent conductive material includes graphene, ITO, AZO, GZO, ZnO, IZO and other materials. The materials of the first contact structure 20, the second contact structure 30 and the connecting structure 60 include metal such as Cr, Ti, W, Au, Al, Rh, In, Sn, Ni, Pt, Ag, V and other metals, a laminated stack or an alloy of the above materials. The first contact structure 20, the second contact structure 30 and the connecting structure 60 can be formed in the same process or different processes. The first contact structure 20, the second contact structure 30 and the connecting structure 60 can include the same metal stack or different metal stacks.

A current blocking structure 23 is formed on the trench 36 under the connecting structures 60, more specifically, the current blocking structure 23 covers the top surface 10a of the substrate 10 in the trench 36, and the opposite sidewalls of the units C1 and C2 near the trench 36, and further extends onto the units C1 and C2 of the semiconductor stack 12. In one embodiment shown in FIGS. 1A and 1B, parts of the current blocking structure 23 is formed under the transparent conductive layer 18 and the second finger parts 302. The parts of the current blocking structure 23 are disposed along the second finger parts 302 and can block current from directly injecting into the semiconductor stack 12 right below the second contact structures 30, thereby increasing lateral current spreading. The material of the current blocking structure 23 includes insulating materials, such as silicon oxide, silicon nitride, silicon oxynitride, niobium oxide, hafnium oxide, titanium oxide, magnesium fluoride, aluminum oxide, and the like. The current blocking structure 23 can be a single layer or a multi-layered stack. In one embodiment (not shown), the current blocking structure 23 includes a plurality of first insulating layers with a first refractive index and a plurality of second insulating layers with a second refractive index alternately stacked, wherein the first refractive index and the second refractive index are different. In another embodiment (not shown), the current blocking structure 23 can be further formed under the second contact structure 30 on the second unit C2, and/or under the first finger part 202 on the second unit C2, for the purpose of current distribution. In another embodiment, the current blocking structure 23 can includes a plurality of current blocking units separated from each other (not shown) disposed under and corresponding to any one of the first contact structure 20, the second contact structure 30, and the connecting structure 60. In another embodiment (not shown), the current blocking structure 23 includes two separated current blocking units disposed under the two connecting structures 60, respectively.

A first insulating structure 50 covers the first unit C1, the second unit C2 and the trench 36, and includes openings 501 and 502 exposing the first contact structure 20 and the second contact structure 30, respectively. More specifically, the opening 501 exposes the first contact part 201 and the opening 502 exposes the second contact part 301. The first insulating structure 50 can be a single layer or a multi-layered stack. The material of the first insulating structure 50 includes insulating materials, such as silicon oxide, silicon nitride, silicon oxynitride, niobium oxide, hafnium oxide, titanium oxide, magnesium fluoride, aluminum oxide, and the like. In one embodiment (not shown), the first insulating structure 50 includes a plurality of first sub-layers with a first refractive index and a plurality of second sub-layers with a second refractive index alternately stacked, wherein the first refractive index and the second refractive index are different. The first insulating structure 50 can reflect light within a specific wavelength range and/or a specific incident angle range, that is, the first insulating structure 50 can be a reflective structure. For example, the first insulating structure 50 has a reflectance of more than 60% of the dominant wavelength and/or the peak wavelength of the light-emitting device 1. In one embodiment, the first insulating structure 50 includes distributed Bragg reflector.

In another embodiment, the first insulating structure 50 further includes additional layers other than the first sub-layers and the second sub-layers. For example, the first insulating structure 50 further includes a bottom layer (not shown). The bottom layer is formed on the semiconductor stack 12 first, and then the first sub-layers and the second sub-layers are formed on the bottom layer. In one embodiment, the bottom layer includes insulating material and the thickness thereof is greater than those of the first sub-layer and the second sub-layer. In one embodiment, the bottom layer can be formed by a process same as that for forming the first sub-layer and the second sub-layer. For example, the bottom layer, the first sub-layers and the second sub-layers are formed by chemical vapor deposition (CVD) or physical vapor deposition (PVD). For example, the bottom layer, the first sub-layers and the second sub-layers are formed by PVD, such as evaporation, sputtering, or a combination thereof, to get a smoother surface of the first insulating structure 50. In another embodiment, the bottom layer can be formed by a process different from that for forming the first sub-layer and the second sub-layer. For example, the bottom layer is formed by CVD, such by plasma enhanced chemical vapor deposition (PECVD). The first sub-layers and the second sub-layers are formed by PVD, such as evaporation or sputtering. In one embodiment, the bottom layer can protect the light-emitting device or the semiconductor stack. For example, the bottom layer prevents moisture from penetrating the light-emitting device.

In another embodiment, the first insulating structure 50 further includes a top layer (not shown). In other words, the first sub-layers and the second sub-layers are formed on the semiconductor stack 12 first, and then the top layer is formed. The thickness of the top layer is greater than the thicknesses of the first sub-layer and the second sub-layer. In one embodiment, the top layer can be formed by a process different from that for forming the first sub-layer and the second sub-layer. For example, the top layer is formed by CVD, such as PECVD. The first sub-layers and the second sub-layers are formed by sputtering or evaporating. In one embodiment, the top layer can improve the robustness of the first insulating structure 50. For example, when the first insulating structure 50 is subject to an external force, the top layer can prevent the first insulating structure 50 from being broken and damaged due to the external force.

In another embodiment, the first insulating structure 50 further includes a dense layer (not shown). In one embodiment, the dense layer can be formed by atomic layer deposition (ALD). The dense layer can be formed on the transparent conductive layer 18 and the semiconductor stack 12 to directly cover the semiconductor stack 12. In one embodiment, the dense layer can be conformably formed on the semiconductor stack 12. Due to the characteristic of good step coverage of the dense layer, the dense layer can protect the semiconductor stack 12, such as preventing moisture from entering the semiconductor stack 12. In the embodiment with the dense layer directly cover the semiconductor stack 12 and is between the semiconductor stack 12 and the plurality of first sub-layers and the second sub-layers, the dense layer can increase the adhesion between the first insulating structure 50 and the semiconductor stack 12, thereby improving the reliability of the light-emitting device. In another embodiment, the dense layer can be formed at the most top of the first insulating structure 50. In one embodiment, the dense layer can reduce or prevent diffusion of metal elements from the following pad electrode formed thereon into the semiconductor stack 12 through defects of the first insulating structure 50. The dense layer also can increase the adhesion between the first insulating structure 50 and the following pad electrode. The material of the dense layer includes silicon oxide, aluminum oxide, hafnium oxide, tantalum oxide, zirconium oxide, yttrium oxide, lanthanum oxide, silicon nitride, aluminum nitride, or silicon oxynitride. The dense layer has a thickness between 50 Å and 2000 Å. In one embodiment, between 100 Å and 1500 Å.

An electrode structure which includes a pad electrode structure and a bonding electrode structure formed thereon is formed on the semiconductor stack 12. The pad electrode structure includes a first pad electrode 20A and a second pad electrode 30A. The bonding electrode structure includes a first bonding electrode 29 and a second bonding electrode 39. More specifically, the first pad electrode 20A and the first bonding electrode 29 compose a first electrode structure, such as an n-type electrode structure, and the second pad electrode 30A and the second bonding electrode 39 compose a second electrode structure, such as a p-type electrode structure. The first electrode structure and the second electrode structure can provide a current path for an external power source to supply power to the semiconductor stack 12. The first pad electrode 20A is filled in the opening 501 thereby connecting the first contact structure 20. The second pad electrode 30A is filled in the opening 502 thereby connecting the second contact structure 30. In this way, the first pad electrode 20A and the second pad electrode 30A are electrically connected with the first semiconductor layer 121 and the second semiconductor layer 122, respectively. A second insulating structure 40 covers the first and the second units C1 and C2, the pad electrode structure 20A and 30A, and the trench 36. The second insulating structure 40 includes a first opening 401 exposing the first pad electrode 20A and a second opening 402 exposing the second pad electrode 30A. The first bonding electrode 29 is filled in the first opening 401 thereby connecting the first pad electrode 20A. The second bonding electrode 39 is filled in the second opening 402 thereby connecting the second pad electrode 30A. The first opening 401 has a similar shape with the first pad electrode 20A and/or the first bonding electrode 29. The second opening 402 has a similar shape with the second pad electrode 30A and/or the second bonding electrode 39.

Parts of the second insulating structure 40 are disposed between the pad electrode structure and the bonding electrode structure. In the embodiment shown in FIG. 1A, a maximum width of the first opening 401 is smaller than maximum widths of the first bonding electrode 29 and the first pad electrode 20A. A maximum width of the second opening 402 is smaller than maximum widths of the second bonding electrode 39 and the second pad electrode 30A. The side surfaces of the pad electrode structure 20A and 30A can be covered and protected by the second insulating structure 40.

The second insulating structure 40 includes insulating material and can be a single layer or a multi-layered stack. In an embodiment, like the first insulating structure 50, the second insulating structure 40 can includes one or a plurality of insulating pairs. Each of the insulating pairs include a plurality of sub-layers with different refractive indexes. In another embodiment, the second insulating structure 40 includes one of a distributed Bragg reflector, a bottom layer, a top layer and a dense layer which are similar to those of the first insulating structure 50 described above. The details of the second insulating structure 40 can be referred to the description of the first insulating structure 50 and is not repeated again. The material of the pad electrode structure and the material of the bonding electrode structure include metal, such as Cr, Ti, W, Au, Al, In, Sn, Ni, Pt, Ag or an alloy or a laminated stack of the above materials. In one embodiment, the pad electrode structure includes reflective metal such as Al, Ag or Rh. The pad electrode structure with reflective metal and the first insulating structure 50 compose an omni-directional reflector (ODR). In one embodiment, a thickness of the pad electrode structure ranges between 1 to 15 μm and a thickness of the bonding electrode structure ranges between 1 to 15 μm. In one embodiment, the thickness of the bonding electrode structure is greater than of the pad electrode structure. A total thickness of the pad electrode structure and the bonding electrode structure stacked thereon ranges between 2 to 30 μm. In another embodiment, the total thickness of the pad electrode structure and the bonding electrode structure stacked thereon ranges between 5 to 30 μm.

In one embodiment, in a plan view, the pad electrode structure and the bonding electrode structure right on the pad electrode structure have similar shapes. The first opening 401 and the first electrode structure have similar shapes. The second opening 402 and the second electrode structure have similar shapes. For example, as shown in FIG. 1A, the shape of the first pad electrode 20A (or the second pad electrode 30A) is an enlargement of the shapes of the first bonding electrode 29 (or the second bonding electrode 39) and the first opening 401 (or the second opening 402). Nevertheless, the present embodiment is not limited thereto. The shapes of the first opening 401 and the second opening 402 can be different from the first electrode structure and the second electrode structure, respectively.

In the plan view, the electrode structure includes a slit set. More specifically, as shown in FIG. 1A, the first electrode structure includes a first slit set S1 with a first slit S11 in the first pad electrode 20A and a second slit S12 in the first bonding electrode 29. The second electrode structure includes a second slit set S2 with a third slit S21 in the second pad electrode 30A and a fourth slit S22 in the second bonding electrode 39. For the conciseness of the description, the details of the slit set and the electrode structure are described by taking the first slit S11, the second slit S12, the first slit set S1 and the first electrode structure (20A and 29) as an example. People who have skills in the art can understand the details of the second slit set S2, the third slit S21, the fourth slit S22 and the second electrode structure (30A and 39) through the following disclosures.

As shown in FIGS. 1A and 1C, the first slit S11 cuts through the first pad electrode 20A in Z-direction and the second slit S12 cuts through the first bonding electrode 29 in Z-direction. In other words, the depth of the first slit S11 is equal to the thickness of the first pad electrode 20A and the depth of the second slit S12 is equal to the thickness of the first bonding electrode 29. In another embodiment (not shown), the first slit S11 does not completely cuts through the first pad electrode 20A and the second slit S12 cuts through the first bonding electrode 29 in Z-direction, and therefore the depth of the first slit S11 is smaller than the thickness of the first pad electrode 20A. The second slit S12 overlaps and corresponds to the first slit S11. The second slit S12 and the first slit S11 extend along the same direction on XY-plane. The widths or the lengths of the first slit S11 and the second slit S12 are the same as or different from each other. In one embodiment, the portion of the second slit S12 overlapped with the first slit S11 has a length more than 50% of the total length of the second slit S12. In one embodiment, in the plan view, center lines of the first slit S11 and the second slit S12 are substantially aligned.

The first slit S11 has a width smaller than that of the second slit S12, wherein the width of the first slit S11 ranges between 3 to 30 μm and the width of the second slit S12 ranges between 8 to 40 μm. In one embodiment, as shown in the plan view, the recess and the first contact structure 20 are located in a region outside the first slit set S1 and/or the second slit set S2. Both the recess and the first contact structure 20 do not overlap the first slit set S1 and/or the second slit set S2. The width of the first slit S11 is smaller than a width W of the recess. In one embodiment, in the plan view, the first slit set S1 and the second slit set S2 extend in a parallel direction. For example, as shown in FIG. 1A, the first slit set S1 and the second slit set S2 extend along X-direction. In another embodiment, the first slit set S1 and the second slit set S2 extend in different directions. For example, the first slit set S1 extends along X-direction and the second slit set S2 extends along Y-direction. Nevertheless, the first slit set S1 and the second slit set S2 can extend along any directions on the XY-plane, and the first slit set S1 and the second slit set S2 can extend straight or have curves. In one embodiment shown in FIG. 1A, the first electrode structure (20A and 29) and the second electrode structure (30A and 39) are separated apart by a gap in X-direction. The first slit set S1 and the second slit set S2 respectively extend from the sides of the first electrode structure and the second electrode structure, which are adjacent to the gap, along the X-direction. The amount of the first slit set S1 and the amount of the second slit set S2 can be more than one, and the two amounts can be the same of different.

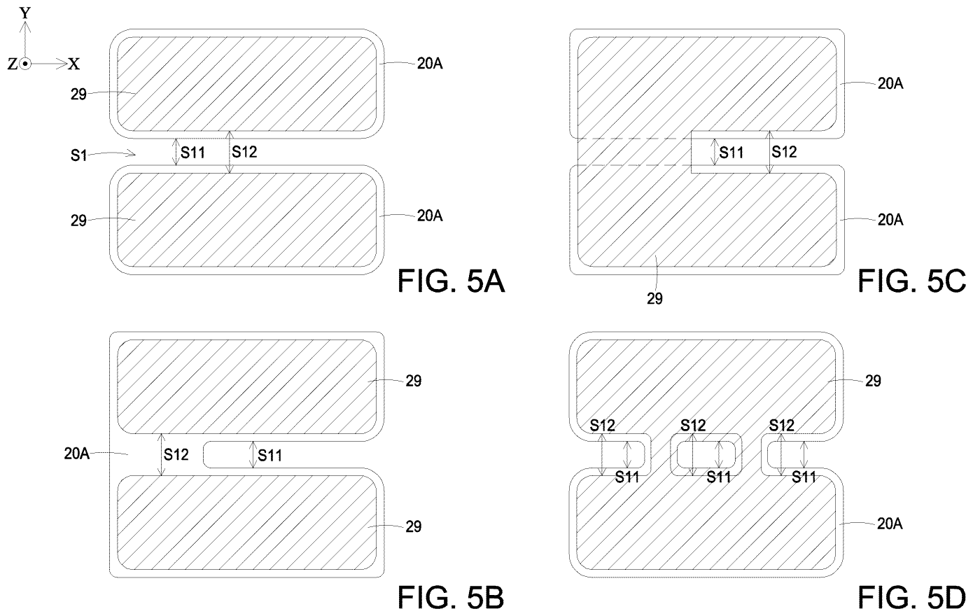

In one embodiment, as shown in FIG. 1A, the first slit set S1 does not extend through the first electrode structure on XY-plane. In other words, as shown in FIG. 1A, the first electrode structure (20A and 29) includes one part at one side of the first slit set S1 and the other part at the other side of the first slit set S1, and the two parts are connected with each other at the left side of the first electrode structure. FIGS. 5A-5D show schematic top views of the first pad electrode 20A and the first bonding electrode 29 in accordance with modified embodiments of the present application. In another embodiment shown in FIG. 5A, the first slit set S1 can extend through the first electrode structure (20A and 29) on XY-plane. That is, the first slit S11 extends through the first pad electrode 20A and the second slit S12 extends through the first bonding electrode 29 in the plan view. The first electrode structure can be divided into a plurality of separated parts by the first slit set S1. In still another embodiment shown in FIG. 5B, the first slit S11 does not extend through the first pad electrode 20A and the second slit S12 extends through the first bonding electrode 29. In this way, the first bonding electrode 29, disposed on the first pad electrode 20A, can be divided into a plurality of separated parts by the second slit S12. In still another embodiment shown in FIG. 5C, the first slit S11 extends through the first pad electrode 20A and the second slit S12 does not extend through the first bonding electrode 29. The first pad electrode 20A can be divided into a plurality of separated parts by the first slit S11. The first bonding electrode 29 is disposed on the plurality of separated parts and covers portion of the first slit S11. In still another embodiment shown in FIG. 5D, the first slit S11 and/or the second slit S12 can be composed of a plurality of discrete slits.

FIG. 1D is a simplified plan view of the light-emitting device 1 which only shows the substrate 10, the semiconductor stack 12, the recesses, the first bonding electrode 29 and the second bonding electrode 39. The second slit S12 is enclosed by a first pseudo edge (E1) which extends from a contour of the first bonding electrode 29 thereby having a first area A1. An area of the first bonding electrode 29 and the first area A1 compose a total area A_{T}1, wherein A1/A_{T}1 ranges between 5-30%. In the same way, the fourth slit S22 is enclosed by a second pseudo edge (E2) which extends from a contour of the second bonding electrode 39 thereby having a second area A2. An area of the second bonding electrode 39 and the second area A2 compose a total area A_{T}2, wherein A2/A_{T}2 ranges between 5-30%. The first area A1 and the second area A2 can be the same or different. The ratio can also be applied in the bonding electrode structure 29 and 39 of any embodiments of the present application.

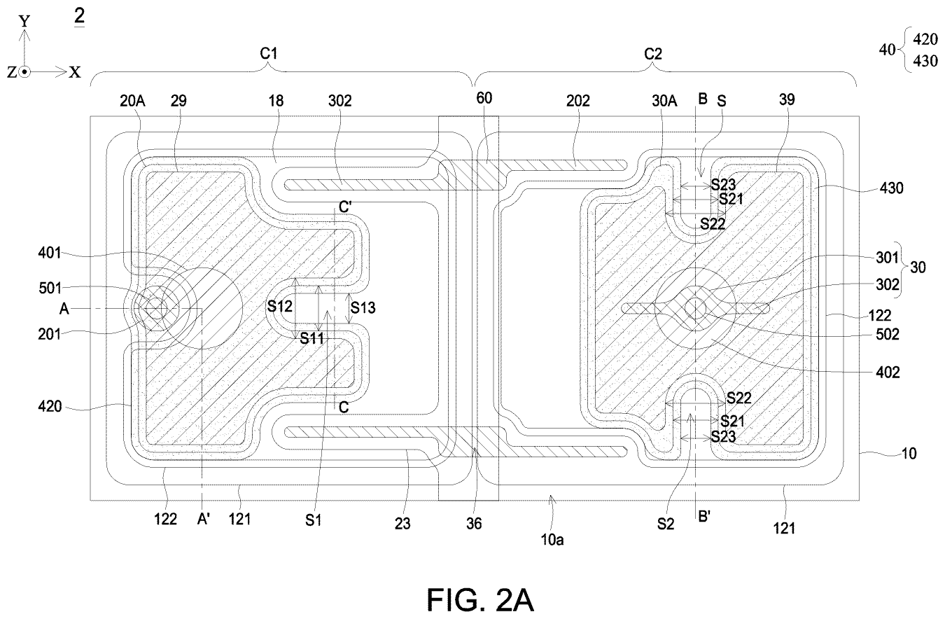

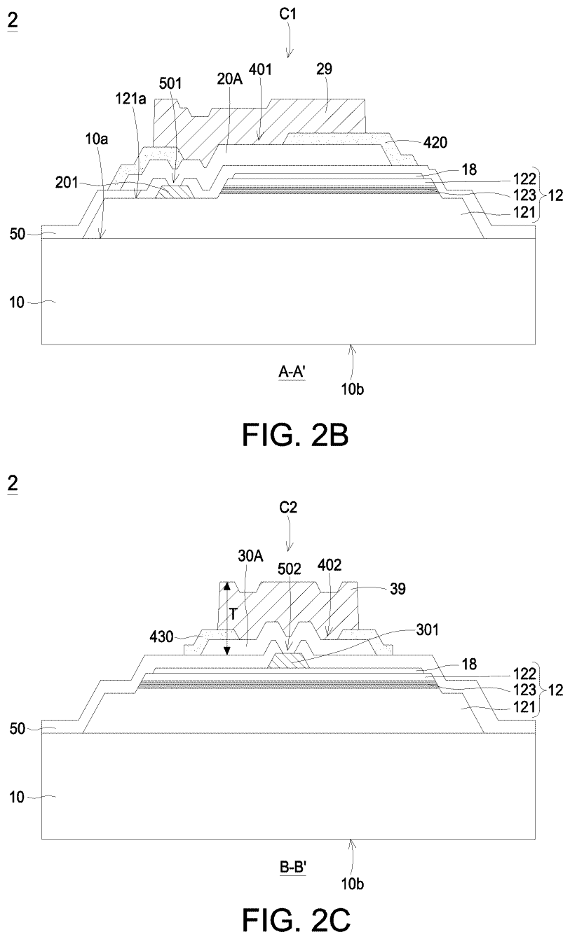

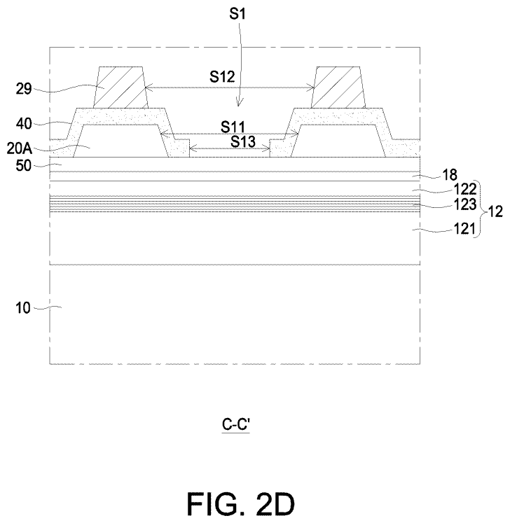

If the details of each elements of the light-emitting device in accordance with any embodiment of the present application, such as material and thickness, are not specifically described in the following descriptions and have the same name and same label as those of the light-emitting device 1, the details can be referred to the description of the light-emitting device 1, and will not be repeated. FIG. 2A shows a plan view of a light-emitting device 2 in accordance with another embodiment of the present application. FIG. 2B shows a cross-sectional view taken along an A-A′ line in FIG. 2A. FIG. 2C shows a cross-sectional view taken along a B-B′ line in FIG. 2A. FIG. 2D shows a cross-sectional view taken along a C-C′ line in FIG. 2A.

Differences between the light-emitting device 2 and the light-emitting device 1 are described in the following. As shown in FIG. 2A, the first slit set S1 extends parallel to X-direction, and the second slit sets S2 extend parallel to Y-direction. The second insulating structure 40 of the light-emitting device 2 includes a first portion 420 having the first opening 401 and a second portion 430 having the second opening 402. The first portion 420 and the second portion 430 are separated by each other and do not overlap in the plan view. The first portion 420 is formed between the first pad electrode 20A and the first bonding electrode 29, and the second portion 430 is formed between the second pad electrode 30A and the second bonding electrode 39. The first bonding electrode 29 is filled in the first opening 401 and connected with the first pad electrode 20A. The second bonding electrode 39 is filled in the second opening 402 and connected with the second pad electrode 30A. In one embodiment, the first portion 420 of the second insulating structure 40 has a similar shape with those of the first pad electrode 20A and the first bonding electrode 29. More specifically, the shape of an outer contour of the first portion 420 is an enlargement of the shapes of the first pad electrode 20A and the first bonding electrode 29. In this way, the side surfaces of the first pad electrode 20A can be covered and protected by the first portion 420. In the same way, the second portion 430 of the second insulating structure 40 has a similar shape with those of the second pad electrode 30A and the second bonding electrode 39. The side surfaces of the second pad electrode 30A can be covered and protected by the second portion 430.

The first portion 420 includes a fifth slit S13 overlapping the first slit set S1, such as the first slit S11 and the second slit S12. The fifth slit S13 is disposed corresponding to the first slit S11 and/or the second slit S12. More specifically, as shown in FIGS. 2A and 2D, the first slit S11, the second slit S12 and the fifth slit S13 overlap and correspond each other. Similar to the first portion 420, the second portion 430 includes two sixth slits S23 overlapping the two second slit set S2, respectively. The sixth slit S23 is disposed corresponding to the third slit S21 and/or the fourth slit S22. For the conciseness of the description, the details of the slits of the first portion 420 and second portion 430 are described by taking the fifth slit S13 as an example. People who have skill in the art can understand the details of the sixth slit S23 through the following disclosures. The fifth slit S13 and the first slit set S1 extend along the same direction on XY-plane. The width or the length of the fifth slit S13 can be the same as or different from those of any one of the first slit S11 and the second slit S12. In one embodiment, in the plan view, central lines of the first slit S1, the second slit S12 and the fifth slit S13 are substantially aligned.

The fifth slit S13 has a width in Y-direction and a length in X-direction which are smaller than those of the first slit S11 and the second slit S12, and the sixth slit S23 has a width in X-direction and a length in Y-direction which are smaller than those of the third slit S21 and the fourth slit S22. It is understood that the widths and the lengths of the fifth slit S13 and the sixth slit S23 are not limited to this example. In one embodiment, the widths of the fifth slit S13 and the sixth slit S23 range between 3 to 30 μm. In one embodiment, a total stacked thickness T of the pad electrode structure, the second insulating structure and the bonding electrode structure ranges between 2 to 30 μm. In another embodiment, the total stacked thickness T of the pad electrode structure, the second insulating structure and the bonding electrode structure ranges between 5 to 30 μm.

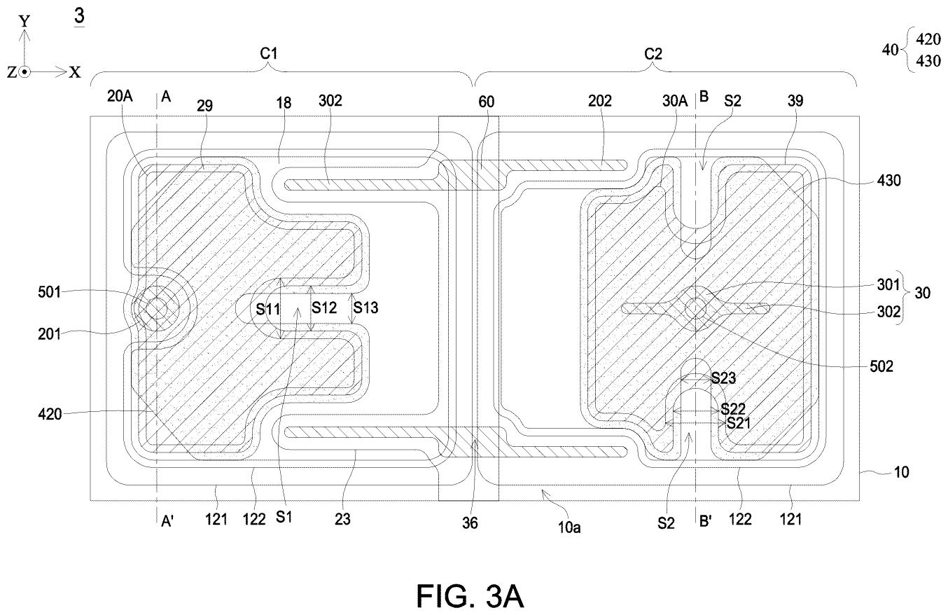

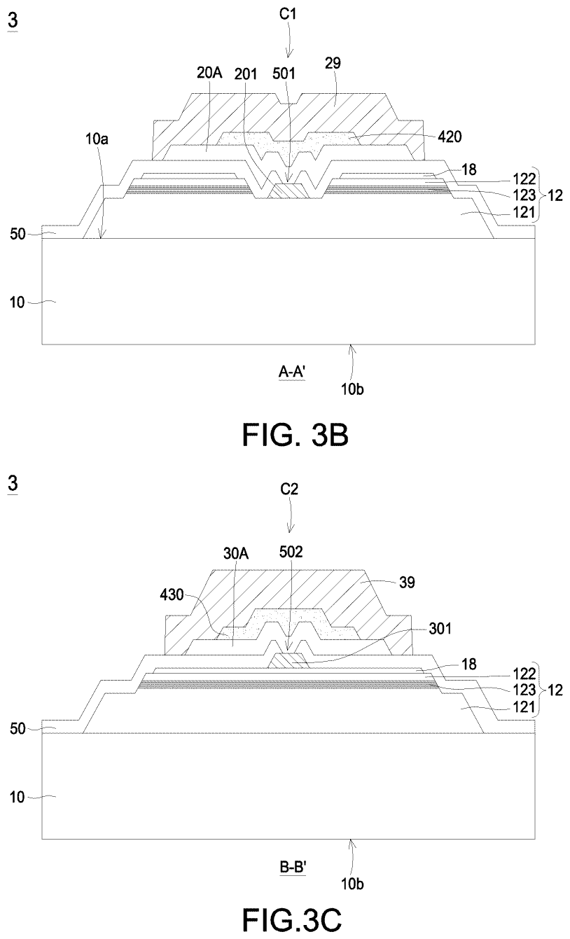

FIG. 3A shows a plan view of a light-emitting device 3 in accordance with another embodiment of the present application. FIG. 3B shows a cross-sectional view taken along an A-A′ line in FIG. 3A. FIG. 3C shows a cross-sectional view taken along a B-B′ line in FIG. 3A. Differences between the light-emitting device 3 and the light-emitting device 2 are described in the following. As shown in FIG. 3A, the second insulating structure 40 of the light-emitting device 3 does not includes the first opening 401 and the second opening 402. Parts of the first pad electrode 20A and the second pad electrode 30A are not covered by the first portion 420 and the second portion 430 of the second insulating structure 40, respectively. For example, as shown in FIG. 3A, the fifth slit S13 has a length in X-direction which is longer than that of the first slit S11 so that a part of the first pad electrode 20A is not covered by the first portion 420 of the second insulating structure 40 and exposed by the fifth slit S13. In the embodiment, Furthermore, two corners of the first pad electrode 20A are not covered by the first portion 420. The first bonding electrode 29 is formed on the first portion 420 and connected with the exposed parts of the first pad electrode 20A. The more exposed parts of the pad electrode structure, the more contact area between the pad electrode structure and the bonding electrode structure, thereby enhancing the electricity characteristic of the light-emitting device. Nevertheless, the positions of the exposed parts of the first pad electrode 20A is not limited thereto. The exposed parts of the first pad electrode 20A can be disposed on other regions in accordance with various shapes of the first portion 420. The first bonding electrode 29 has an area greater than that of the first pad electrode 20A. Thus, the first bonding electrode 29 covers the side surfaces of the exposed parts of the first pad electrode 20A. Metal element such as Al or Ag in the first pad electrode 20A can be protected by the first bonding electrode 29 and prevented from migrating or being corroded. The second pad electrode 30A, the second bonding electrode 39, the sixth slit S23 and the second portion 430 are disposed in a similar way. The details of the second pad electrode 30A, the second bonding electrode 39, the sixth slit S23 and the second portion 430 can be referred to the above descriptions, and will not be repeated.

Various modifications and combinations can be made to the light-emitting devices in accordance with the embodiments of the present application. For example, any one of the first and the second portion of the second insulating structure 40 includes the opening shown in FIG. 2A and the slit which exposes the pad electrode thereunder shown in FIG. 3A. For example, the light-emitting device includes the first electrode structure and the first portion 420 of the light-emitting device 2 and the second electrode structure and the second portion 430 of the light-emitting device 3. In another embodiment, one of the first electrode structure and the second electrode structure includes the slit set. In still another embodiment, the first contact structure 20 can be omitted so that the first pad electrode 20A contacts the first semiconductor layer 121 in the recesses, and/or the second contact structure 30 can be omitted so that the second pad electrode 30A contacts the transparent conductive layer 18 or the second semiconductor layer 122.

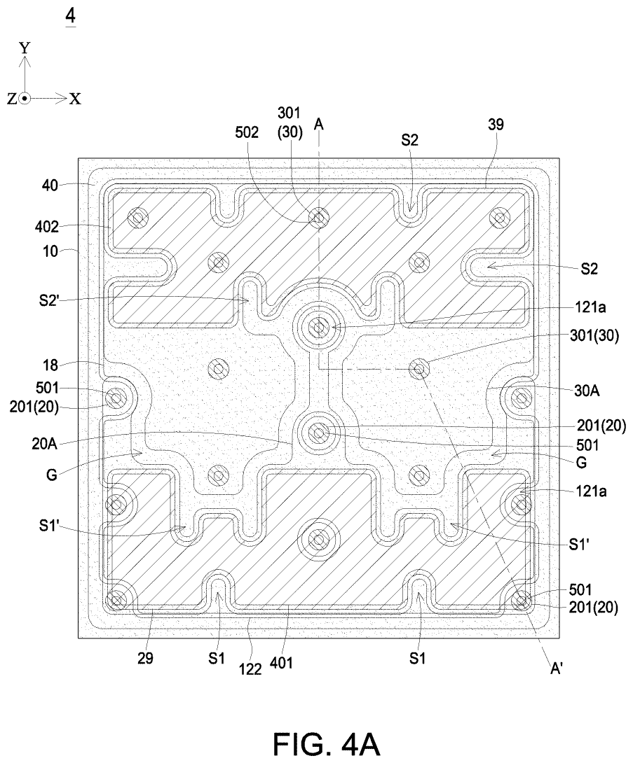

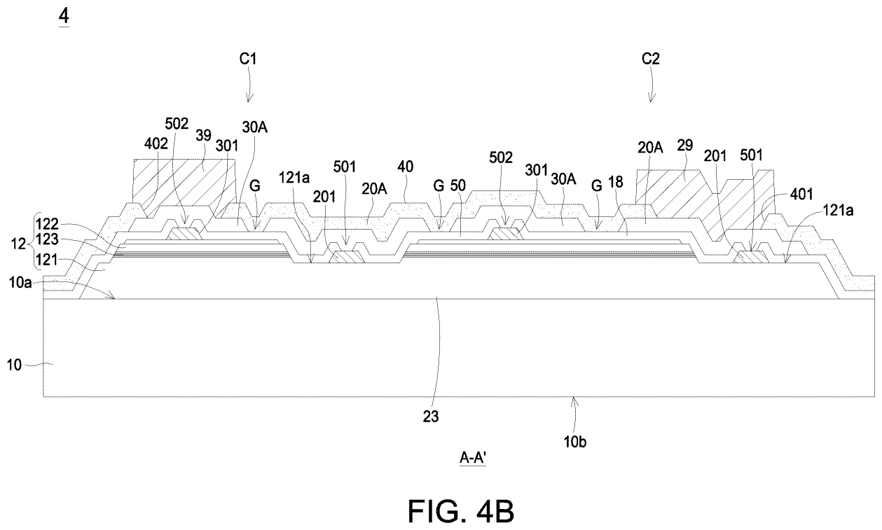

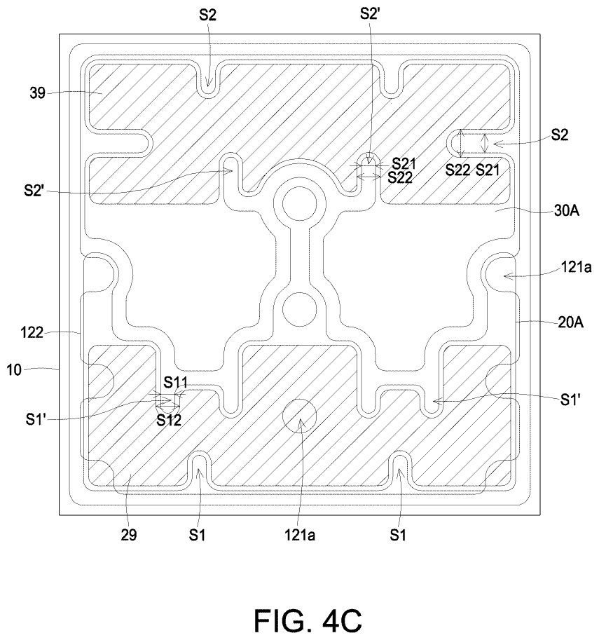

In one embodiment, the semiconductor stack 12 includes a single unit without the connecting structure 60 rather than a plurality of separated units, and the first electrode structure and the second electrode structure are formed on the semiconductor layers having different conductivity types in the single unit. FIG. 4A shows a plan view of a light-emitting device 4 in accordance with another embodiment of the present application. FIG. 4B shows a cross-sectional view taken along an A-A′ line in FIG. 4A. FIG. 4C is a simplified plan view of the light-emitting device 4 which only shows the substrate 10, the semiconductor stack 12, the recesses, the first pad electrode 20A, the second pad electrode 30A, the first bonding electrode 29 and the second bonding electrode 39. Differences between the light-emitting device 4 and the aforementioned light-emitting devices are described in the following.

The semiconductor stack 12 of the light-emitting device 4 includes single unit. The first electrode structure (20A and 29) and the second electrode structure (30A and 39) are formed on the single unit. A plurality of the recesses is formed in the semiconductor stack 12. As shown in FIGS. 4A and 4C, one part of the plurality of the recesses is disposed in a central region of the semiconductor stack 12 surrounding by the semiconductor mesa, and the other part of the plurality of the recesses is at the periphery region of the semiconductor stack 12. The first pad electrode 20A is configured to cover the plurality of the recesses to electrically connecting the first contact structure 20 for current spreading. The second pad electrode 30A is disposed on a region of the semiconductor stack 12 without the first contact structure 20 thereon to electrically connecting the second contact structure 30 for current spreading. The first pad electrode 20A and the second pad electrode 30A are isolated with each other through a gap G. In the plan view, the contours of the first pad electrode 20A and the second pad electrode 30A disposed around two sides of the gap G can be complementary or complementary-like. In one embodiment, a total area of the first pad electrode 20A and the second pad electrode 30A ranges between 20-90% of the area of the semiconductor stack 12. In one embodiment, the first opening 401 and the first bonding electrode 29 have similar shapes. The second opening 402 and the second bonding electrode 39 have similar shapes.

In the plan view of FIG. 4C, the first electrode structure (20A and 29) includes the first slit sets S1 and S1′, and the second electrode structure (30A and 39) includes the second slit sets S2 and S2′. In one embodiment, as shown in FIG. 4C, the first electrode structure (20A and 29) includes two first slit sets S1 located near the periphery region of the semiconductor stack 12 and four first slit sets S1′ located at the center region of the semiconductor stack 12. The second electrode structure (30A and 39) includes four second slit sets S2 located near the periphery region of the semiconductor stack 12 and two second slit sets S2′ located at the center region of the semiconductor stack 12. Due to the configuration of the first slit sets S1′ of the first electrode structure and the second slit sets S2′ of the second electrode structure, the contour of the first pad electrode 20A and the contour of the second pad electrode 30A do not fit each other, for example, the first pad electrode 20A does not extent into the second slit sets S2′ of the second electrode structure, so that the contours of the first pad electrode 20A and the second pad electrode 30A are not completely complementary, but complementary-like. In another embodiment (not shown), all the first slit sets S1, S1′ and all the second slit sets S2, S2′ are located near the two sides of the gap G, the contours of the first pad electrode 20A and the second pad electrode 30A adjacent to the gap G are complementary-like. In another embodiment (not shown), all the slit sets can be located near the periphery region of the semiconductor stack 12 and the contours of the first pad electrode 20A and the second pad electrode 30A adjacent to the gap G can be complementary.

In one embodiment, a width of the first slit 11 of the first slit set S1′ and/or the third slit 21 of the second slit set S2′ can be the same as a width of the gap G. In another embodiment, the plurality of the first slit set S1 has the same or different widths and/or the plurality of the second slit set S2 has the same or different widths.

Various modifications and combinations can be made to the light-emitting device 4 in accordance with the embodiments of the present application. For example, the first pad electrode 20A has a similar shape as the first bonding electrode 29 and the second pad electrode 30A has a similar shape as the second bonding electrode 39 like the aforementioned embodiments. The contours of pad electrodes 20A and 30A are not complementary. In another embodiment, any one of the first contact structure 20 and the second contact structure 30 may further includes finger part extending from the contact part 201 or 301 for current spreading. In still another embodiment, the first contact structure 20 can be omitted so that the first pad electrode 20A contacts the first semiconductor layer 121 in the recesses, and/or the second contact structure 30 can be omitted so that the second pad electrode 30A contacts the transparent conductive layer 18 or the second semiconductor layer 122.

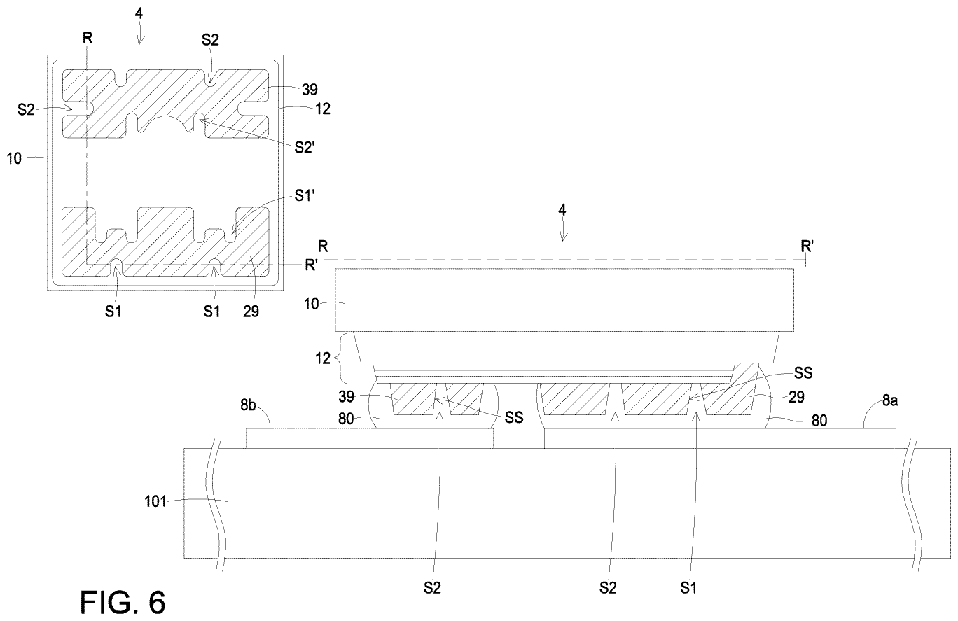

FIG. 6 shows a cross-sectional view of a semiconductor module 100 in accordance with an embodiment of the present application. The semiconductor module 100 includes a carrier 101 and the semiconductor devices in accordance with any embodiments of the present application fixed on the carrier 101. In order to show the slit set of the electrode structure in the semiconductor module 100, the light-emitting device 4 is taken as an example applied in the semiconductor module 100 and the cross-sectional view shown in FIG. 6 passes R-R′ line of the light-emitting device 4. The semiconductor module 100 can be a light-emitting module. It is also noted that, the details of the elements of the light-emitting device 4 are omitted to make FIG. 6 clear.

As shown in FIG. 6, the carrier 101 is provided with terminal pads 8a and 8b. In one embodiment, the carrier 101 includes a circuit board. The first bonding electrode pad 29 and the second bonding electrode pad 39 of the light-emitting devices in accordance with any embodiments of the present application are connected and attached to the terminal pads 8a and 8b through a conductive adhesive element 80 in a flip-chip manner. In this way, most light emitted by the semiconductor stack 12 is extracted through the backside surface and/or the side surfaces of the substrate 10. In another embodiment (not shown), the light-emitting device in accordance with any embodiments of the present application is devoid of the substrate 10, and light is extracted through the side of the semiconductor stack 12 opposite to the electrode structures. In one embodiment, the conductive adhesive element 80 includes a base in which conductive particles are dispersed. The conductive adhesive element 80 can be formed of, for example, thermal curing resin or ultraviolet curing resin. The conductive adhesive element 80 includes anisotropic conductive adhesive, and isotropic conductive adhesive such as silver paste, without being limited thereto. In the aforementioned descriptions, the width of the slit of the pad electrode structure ranges between 3 to 30 μm and the width of the slit of the bonding electrode structure ranges between 8 to 40 μm. In this way, the conductive adhesive element 80 is not only disposed between the outer surfaces of the bonding electrode structure but also filled in the slit sets S1 and S2. Therefore, the light-emitting device can be fixed on the carrier 101 by the conductive adhesive element 80. In addition, if the conductive adhesive element 80 overflows during flip-chip bonding process, the slit sets S1 and S2 accommodate the overflowed conductive adhesive element 80, reducing the risk of an electrical short circuit between the two pad electrode structures. In some embodiment, more areas of the side surfaces SS of the slit set can increase the contact area between the electrode structure and the conductive adhesive element 80, thereby enhancing the adhesion between the light-emitting device and the carrier 101.

In one embodiment, the light-emitting module 100 can further include an encapsulant (not shown) formed on the carrier 101 and covering the light-emitting device. The encapsulant includes transparent material, such as silicone, epoxy, acrylic or a combination thereof. In another embodiment (not shown), the light-emitting module 100 includes the carrier 101 and a plurality of light-emitting packages mounted on the carrier 101, and the light-emitting device in accordance with any of the embodiments is encapsulated in the light-emitting package and mounted on the carrier 101 in flip-chip manner. The light-emitting package (not shown) includes leads and a body with a cavity. The light-emitting device in accordance with any embodiments of the present application is set in the cavity, and the first bonding electrode pad 29 and the second bonding electrode pad 39 of the light-emitting device are connected and attached to the leads through the conductive adhesive element 80. The conductive adhesive element 80 can be filled in the slit sets S1 and S2 so that the light-emitting device can be fixed on the leads in the package. The light-emitting package can further include an encapsulant filled in the cavity and covering the light-emitting device.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting device, comprising:
a semiconductor stack, comprising a first semiconductor layer, an active region and a second semiconductor layer;
an electrode structure, formed on and electrically connected with the semiconductor stack, comprising a pad electrode structure and a bonding electrode structure formed on the pad electrode structure; and
a first insulating structure formed on the pad electrode structure;
wherein the electrode structure comprises a first slit set, the first slit set comprises a first slit in the pad electrode structure and a second slit in the bonding electrode structure, and
in a plan view, the second slit overlaps and corresponds to the first slit.

2. The light-emitting device according to claim 1, further comprising:
a contact structure formed on the semiconductor stack; and
a second insulating structure formed on the semiconductor stack, comprising an opening exposing the contact structure;
wherein the pad electrode structure is formed on the second insulating structure, filled in the opening and connected to the contact structure.

3. The light-emitting device according to claim 1, wherein the semiconductor stack comprises a recess exposing an upper surface of the first semiconductor layer, the pad electrode structure comprises a first pad electrode electrically connected with the first semiconductor layer through the recess, the first slit is in the first pad electrode, and
in the plan view, the first slit has a width smaller than that of the recess.

4. The light-emitting device according to claim 3, wherein in the plan view, the recess is located in a region outside the first slit set.

5. The light-emitting device according to claim 1, wherein a width of the second slit ranges between 8 to 40 μm.

6. The light-emitting device according to claim 1, wherein in the plan view, the first slit has a width smaller than that of the second slit.

7. The light-emitting device according to claim 1, wherein the first insulating structure comprises a first opening exposing the electrode structure, and
the bonding electrode structure is filled in the first opening and connected with the pad electrode structure.

8. The light-emitting device according to claim 7, wherein a maximum width of the first opening is smaller than maximum widths of the bonding electrode structure and the pad electrode structure.

9. The light-emitting device according to claim 1, a total thickness of the pad electrode structure and the bonding electrode structure ranges between 2 to 30 μm.

10. The light-emitting device according to claim 1, wherein in the plan view, the second slit is enclosed by a pseudo edge which extends from a contour of the bonding electrode structure thereby having a first area A1, an area of the bonding electrode structure and the first area compose a total area A_{T}, wherein A1/A_{T} ranges between 5-30%.

11. The light-emitting device according to claim 1, wherein:
the pad electrode structure comprises a first pad electrode electrically connected with the first semiconductor layer and a second pad electrode electrically connected with the second semiconductor layer, and
the bonding electrode structure comprises a first bonding electrode electrically connected to the first pad electrode and a second bonding electrode electrically connected to the second pad electrode.

12. The light-emitting device according to claim 11, wherein the first insulating structure comprises a first portion and a second portion separated by each other,
in the plan view, the first portion and the second portion are devoid of overlapping,
the first portion is formed between the first pad electrode and the first bonding electrode, and
the second portion is formed between the second pad electrode and the second bonding electrode.

13. The light-emitting device according to claim 12, wherein each of the first portion and the second portion comprises a third slit, and in the plan view, the third slit in one of the first portion and the second portion overlaps and corresponding to the first slit.

14. The light-emitting device according to claim 13, wherein a part of the first pad electrode is not covered by the first portion and exposed from the third slit in the first portion, and the first bonding electrode connects to the part of the first pad electrode through the third slit in the first portion, and/or a part of the second pad electrode is not covered by the second portion and exposed from the third slit in the second portion, and the second bonding electrode connects to the part of the second pad electrode through the third slit in the second portion.

15. The light-emitting device according to claim 13, wherein the first portion comprises a second opening and the first bonding electrode is filled in the second opening and connected to the first pad electrode, and/or the second portion comprises a third opening and the second bonding electrode is filled in the third opening and connected to the second pad electrode.

16. The light-emitting device according to claim 12, wherein a total stacked thickness of the pad electrode structure, the first insulating structure and the bonding electrode structure ranges between 2 to 30 μm.

17. The light-emitting device according to claim 11, wherein in the plan view, contours of the first pad electrode and the second pad electrode are complementary or complementary-like.

18. The light-emitting device according to claim 11, wherein the electrode structure further comprises a second slit set,
the second slit set comprises a fourth slit disposed in the second pad electrode and a fifth slit disposed in the second bonding electrode, and
wherein the first slit is disposed in the first pad electrode and the second slit is disposed in the first bonding electrode.

19. The light-emitting device according to claim 11, further comprising a connecting structure;
wherein the semiconductor stack comprises a plurality of units separated by each other, and the plurality of units comprises a first unit and a second unit,
the connecting structure is formed between and electrically connects the first unit and the second unit, and
the first pad electrode and the first bonding electrode are formed on the first unit, and the second pad electrode and the second bonding electrode are formed on the second unit.

20. A light-emitting module, comprising:
a carrier;
a terminal pad on the carrier;
a conductive adhesive element; and
the light-emitting device according to claim 1;
wherein the bonding electrode structure is connected to the terminal pad by the conductive adhesive element, and
the conductive adhesive element is filled in the first slit set.
